(19) United States
(12) Patent Application Publication
(10) Pub. No.: US 2005/0180227 A1
(43) Pub. Date: Aug. 18, 2005

(54) Booster circuit

(75) Inventor: Hiroyuki Kitajima, Shiga (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/053,957

(22) Filed: Feb. 10, 2005

(30) Foreign Application Priority Data
Feb. 16, 2004 (JP) 2004-037571

(51) Int. Cl. G11C 5/00

(52) U.S. Cl. 365/189.09

(57) ABSTRACT

According to one aspect of the present invention, a booster circuit comprises a charge pump, a voltage supply section reducing a power supply voltage and supplying a voltage to the charge pump through an output metal-oxide-semiconductor (MOS) transistor of an operational amplifier and a drive MOS transistor maximizing a drive capacity of the output MOS transistor of the operational amplifier.

### BACKGROUND OF THE INVENTION

1. Field of the invention

The present invention relates to booster circuits and, particularly, to a booster circuit having a charge pump and a voltage supply section that outputs a supply voltage to the charge pump.

2. Description of Related Art

A display unit of a portable device such as a mobile phone and PDA is driven by a driver IC. The driver IC includes a booster circuit that receives power from a battery. Normally, a charge pump is used as the booster circuit.

A basic circuit of the charge pump is explained hereinafter with reference to FIG. 3. FIG. 3 shows a double boosting charge pump. The charge pump 10 has a booster capacitor 11, a smoothing capacitor 12, and switches 13, 14, 15, and 16. The switch 13, the booster capacitor 11, and the switch 14 are connected in series between a power supply line VDC and a ground line Gnd. The switch 15 is connected between the power supply line VDC and the connection node of the booster capacitor 11 with the switch 14. The switch 16 and the smoothing capacitor 12 are connected in series between the connection node of the switch 13 with the booster capacitor 11 and a ground line Gnd. The output terminal of the charge pump 10 is the connection node of the switch 16 with the smoothing capacitor 12.

The switches 13 and 14 and the switches 15 and 16 are respectively complementary on/off controlled by a clock signal CLK. The switches 13, 14, 15, and 16 are each composed of a MOS transistor, for example.

A basic boosting operation of the charge pump 10 is described below. First, an “H” level clock signal CLK is input to turn on the switches 13 and 14 and turn off the switches 15 and 16. The booster capacitor 11 is thereby charged with the power supply voltage VDC. Then, an “L” level clock signal CLK is input to turn off the switches 13 and 14 and turn on the switches 15 and 16. The booster capacitor 11 thereby discharges and a boosted voltage Vo of a charged voltage to the booster capacitor 11 plus the power supply voltage VDC is output to the output terminal and also charged to the smoothing capacitor 12. The on/off control is repeated in this way so that the boosted voltage Vo is output to the output terminal of the charge pump 10.

The charge pump 10 is on/off controlled by the clock signal CLK in such a way that the charged voltages to the capacitors 11 and 12 are saturated. The boosted voltage Vo which is twice the power supply voltage VDC is thus output to the output terminal of the charge pump 10.

In a mobile terminal or the like, a battery is directly connected to the power supply line VDC of the charge pump 10. For example, connecting a battery with a power supply voltage VDC=3V results in output of a boosted voltage of Vo=2*VDC=6V from the charge pump 10.

A circuit that receives the output voltage Vo from the charge pump 10 as a power supply may be configured by a low voltage process of a withstand voltage 5.5V, for example. To output the boosted voltage of Vo=2*VDC=5.4V from the charge pump 10, for example, a battery of the power supply voltage VDC=2.7V can be used. However, if a user of the driver IC including the charge pump 10 prefers to use a battery of the power supply voltage VDC=3V, it is necessary to step down the supply voltage VDC from 3V to 2.7V before supplying the voltage to the charge pump 10. For such a case, the technique disclosed in Japanese Unexamined Patent Application Publication No. 2001-339939 uses a booster circuit having a step-down section. In this technique, the step-down section reduces a power supply voltage VDC and supplies the reduced voltage to the charge pump.

A booster circuit 100 of this related art is described hereinafter with reference to FIG. 4. The booster circuit 100 has a charge pump 10 and a voltage supply section 20.

The voltage supply section 20 receives a power supply voltage VDC and an n-bit data in accordance with the power supply voltage VDC used.

The voltage supply section 20 has a digital/analog (D/A) converter 21 and an operational amplifier 22. The D/A converter 21 converts a power supply voltage VDC into a voltage Vdac corresponding to a supply voltage Vci based on the input n-bit data. The operational amplifier 22 converts the impedance of the output voltage Vdac of the D/A converter 21 into a supply voltage Vci.

For example, in order to obtain the output voltage Vdac=2.7V using the power supply voltage VDC=3V, 3 bit data “000” is set as an n-bit data to the D/A converter. On the other hand, in order to obtain the output voltage Vdac=2.7V using the power supply voltage VDC=3.3V, 3 bit data “001” is set as an n-bit data to, the D/A converter.

FIG. 5 shows a basic circuit of the operational amplifier 22. The operational amplifier 22 is composed of a differential amplifier stage and an output stage. The differential amplifier stage has P-channel MOS transistors M1 and M2 and N-channel MOS transistors M3 to M5. The output stage has a P-channel MOS transistor M6 and an N-channel MOS transistor M7.

The MOS transistor M6 functions as an output MOS transistor that receives a power supply voltage VDC from a power supply line VDC at its source and outputs a voltage Vout from its drain.

The booster circuit 100 is formed by an integrated circuit of one chip. The booster capacitor 11 and the smoothing capacitor 12 constituting the charge pump 10 are connected to the integrated circuit as external elements. The clock signal CLK may be input to the charge pump 10 from outside of the integrated circuit or from an oscillator circuit placed inside of the integrated circuit.

The operation of the booster circuit 100 having the above configuration is described below. The case of connecting an unused battery with a power supply voltage VDC=3V to the power supply line VDC and outputting an output voltage Vo=5.4V from the charge pump 10 is described hereinafter as an example.

An n-bit data is set so that the output voltage of the D/A converter is Vdac=2.7V. When a power supply voltage VDC=3V is supplied from the battery to the supply line VDC, the D/A converter 21 outputs an output voltage Vdac=2.7V based on the n-bit data. The output voltage Vdac is supplied as a voltage Vci to the charge pump 10 through the operational amplifier 22. The charge pump 10 outputs Vo=2.7*Vci=5.4V to the output terminal Vo.

In some cases, the power supply voltage from the battery decreases from VDC=3V in the unused state to VDC=2.7V, for example, due to battery consumption or the like. In such a case, the booster circuit of the related art changes the n-bit data to the D/A converter 21 to maintain Vdac=2.7V. However, when the output voltage Vdac=2.7V from the D/A converter 21 is output as a supply voltage Vci from the operational amplifier 22, a decreased voltage of VDC=2.7V is used also for the power supply to the operational amplifier. Thus, the output of the operational amplifier 22 as Vci decreases due to the voltage drop by the on-resistance of the output MOS transistor M6, which results in decrease in the output voltage Vo from the charge pump 10. Further, a desired boosted voltage Vo is not output from the charge pump 10 until the power supply voltage VDC of the power supply line VDC rises sufficiently, thus requiring a long time to activate the booster circuit 100. Furthermore, since the operational amplifier 22 operates during the rise time before the charge pump 10 starts outputting a desired boosted voltage, the operational amplifier 22 consumes a current during this time period.

### SUMMARY OF THE INVENTION

According to one aspect of the present invention, a booster circuit comprises a charge pump, a voltage supply section reducing a power supply voltage and supplying a voltage to the charge pump through an output metal-oxide-semiconductor (MOS) transistor of an operational amplifier and a drive MOS transistor maximizing a drive capacity of the output MOS transistor of the operational amplifier.

This allows outputting a desired boosted voltage until the power supply voltage VDC rises even when the power supply voltage VDC is relatively low.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram according to a first embodiment.

FIG. 2 shows an operational amplifier according to the first embodiment.

FIG. 3 is a circuit diagram showing a charge pump.

FIG. 4 is a circuit diagram according to a related art.

FIG. 5 shows an operational amplifier according to a related art.

### PREFERRED EMBODIMENT OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

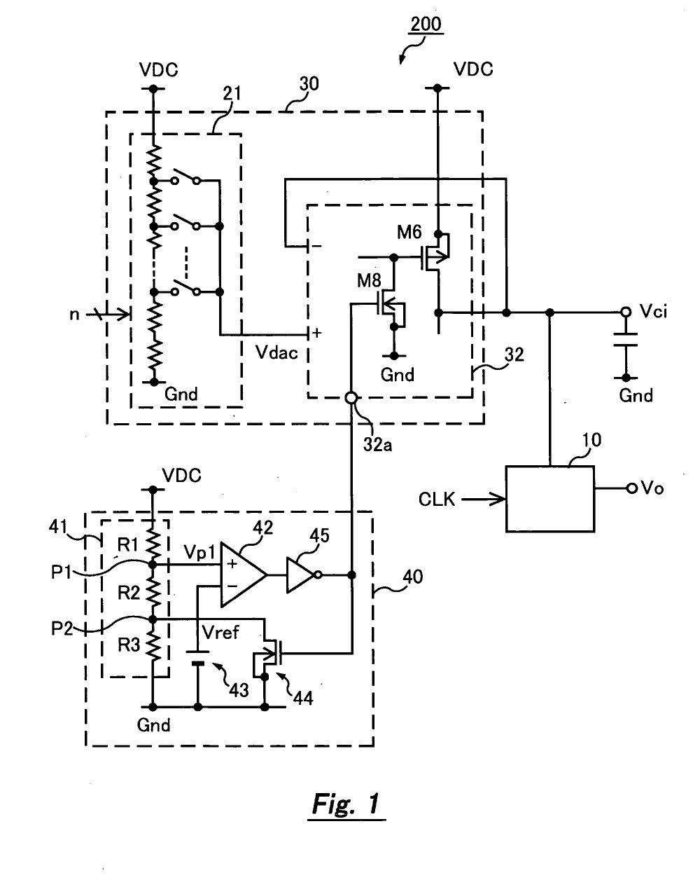

Referring first to FIG. 1, a booster circuit 200 of an embodiment of the present invention is described below. In FIG. 1, the same elements as in FIG. 4 are denoted by the same reference symbols and redundant description is omitted. The booster circuit 200 is different from the booster circuit 100 of FIG. 4 in having a voltage supply section 30 instead of the voltage supply section 20, and further having a control section 40 for controlling the voltage supply section 30.

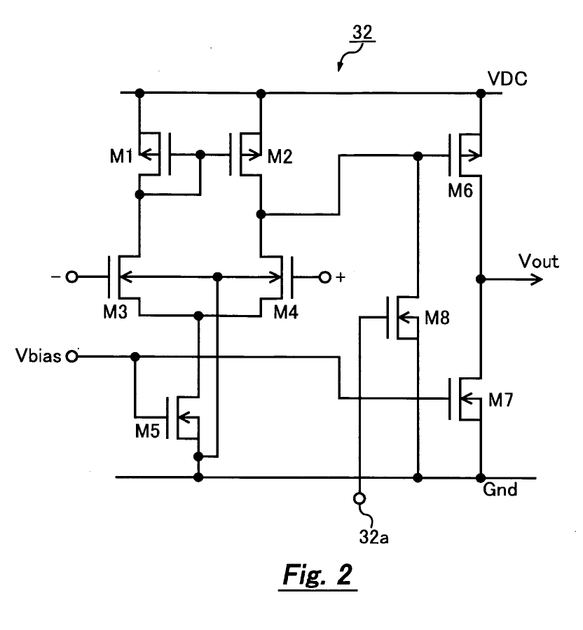

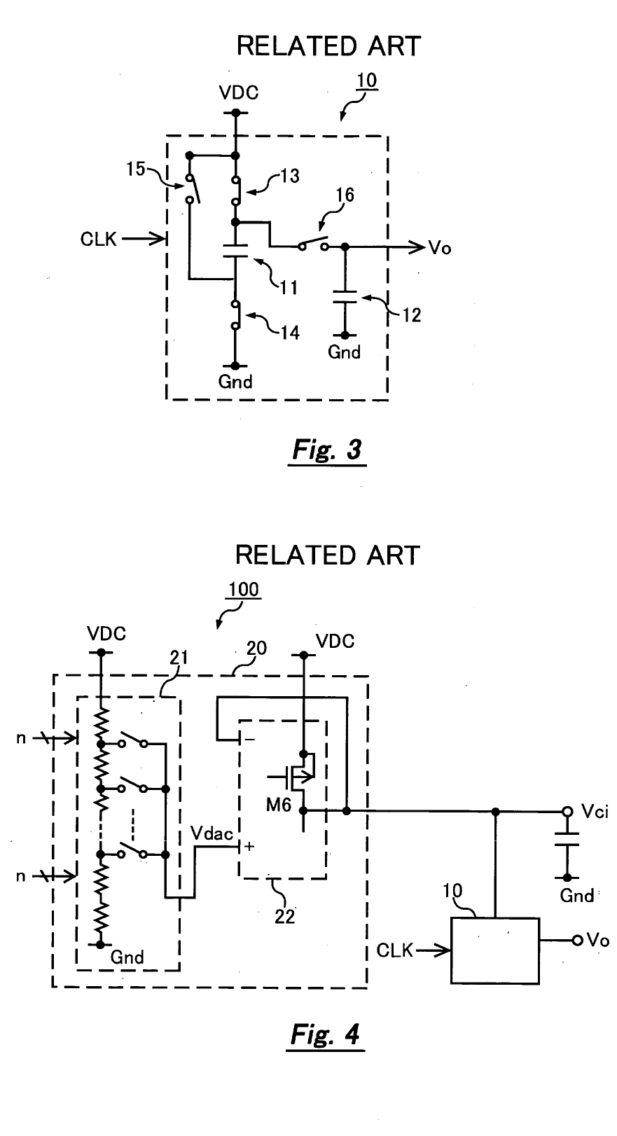

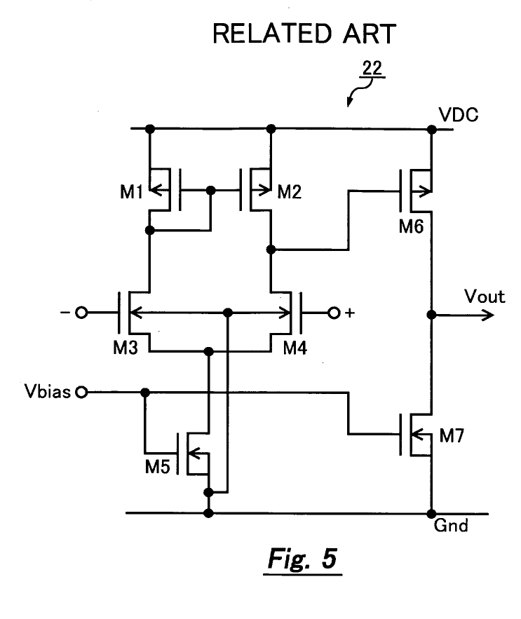

The voltage supply section 30 has an operational amplifier 32 with a control terminal 32a instead of the operational amplifier 22. As shown in FIG. 2, the operational amplifier 32 has an N-channel MOS transistor M8 between the gate of the MOS transistor M6 and the ground in addition to the MOS transistors M1 to M7 having the same configuration as those of the operational amplifier 22. The N-channel MOS transistor M8 is a drive MOS transistor that fully drives the MOS transistor M6. The gate of the MOS transistor M8 is connected to the control terminal 32a. Illustration and description of circuits for off-controlling the circuits other than the MOS transistors M6 and M8 which constitute the operational amplifier 32 are omitted.

In the operational amplifier 32, the MOS transistor M8 is turned on by the control signal to the control terminal 32a. The MOS transistor M8 then turns on and fully drives the MOS transistor M6. The other circuits different from the MOS transistors M6 and M8 which constitute the operational amplifier 32 are off while the MOS transistor M6 is fully driven.

The control section 40 has a voltage divider resistor 41, a comparator 42, a reference voltage generator 43, an N-channel MOS transistor 44, and an inverter 45. The voltage divider resistor 41 is connected between the power supply line VDC and the ground. The non-inverting input terminal of the comparator 42 is connected to a first voltage dividing point P1 of the voltage divider resistor 41. The inverting input terminal of the comparator 42 is connected to the reference voltage generator 43. The N-channel MOS transistor 44 is connected between a second voltage dividing point P2 of the voltage divider resistor 41 and the ground.

The inverter 45 is connected between the output terminal of the comparator 42 and the control terminal 32a of the operational amplifier 32. The output of the inverter 45 is also connected to the gate of the N-channel MOS transistor 44.

The control section 40 detects the power supply voltage VDC at the first voltage dividing point P1 of the voltage divider resistor 41. The comparator 42 compares the detected voltage Vp1 at the first voltage dividing point P1 with a reference voltage Vref from the reference voltage generator 43. The comparison result is output as a control signal through the inverter 45.

In this operation, the MOS transistor 44 serves as a hysteresis MOS transistor to add a hysteresis effect to the detection of the power supply voltage VDC.

The hysteresis effect in the control section 40 is as follows. The MOS transistor 44 is on while the voltage of the non-inverting input terminal (+) of the comparator 42 changes from the level lower than the voltage of the inverting input terminal (−) to the level higher than the same, i.e. while the output of the comparator 42 changes from “L” to “H”. Thus, the voltage at the second voltage dividing point P2 of the voltage divider resistor 41 equals to the ground voltage, and the voltage at the first voltage dividing point P1 is: Vp1=VDC*R2/(R1+R2) Further, the MOS transistor 44 is off while the voltage of the non-inverting input terminal (+) of the comparator 42 changes from the level higher than the voltage of the inverting input terminal (−) to the level lower than the same, i.e. while the output of the comparator 42 changes from “H” to “L”. Thus, the voltage at the first voltage dividing point P1 is: Vp1=VDC*(R2+R3)/(R1+R2+R3). Hence, if the power supply voltage VDC when the output of the comparator 42 changes from “L” to “H” is VDC1 and the VDC when it changes from “H” to “L” is VDC2, the relationship between the VDC1 and the VDC2 is expressed as:

$$VDC1 * R2 / ( R1 + R2 ) = VDC2 * ( R2 + R3 ) / ( R1 + R2 + R3 ) \qquad ( 1 )$$

From the formula (1),

$$VDC1 / VDC2 = ( 1 + R3 / R2 ) / ( 1 + R3 / ( R1 + R2 ) ) > 1 \qquad ( 2 )$$

The formula (2) shows the power supply voltage VDC1 when the output of the comparator 42 changes from “L” to “H” is higher than the power supply voltage VDC2 when it changes from “H” to “L”, indicating that the hysteresis effect is added to the detection of the power supply voltage VDC. It is also possible to use a comparator having the hysteresis effect as a comparator 42 instead of the MOS transistor 44.

The booster circuit 200 is formed by an integrated circuit of one chip. The booster capacitor 11 and the smoothing capacitor 12 constituting the charge pump 10 are connected to the integrated circuit as external elements. The clock signal CLK may be supplied to the charge pump 10 from outside of the integrated circuit or from an oscillator circuit placed inside of the integrated circuit. The n-bit signal is set to the D/A converter 21 from outside of the integrated circuit.

The operation of the booster circuit 200 having the above configuration is described below. The case of connecting an unused battery with a power supply voltage VDC=3V to the power supply line VDC and outputting an output voltage Vo=5.4V from the charge pump 10 is described hereinafter as an example. First, an n-bit data to the D/A converter 21 is set in such a way that the D/A converter 21 outputs the output voltage Vdac=2.7V. The data is set to output the voltage of 2.7V, which is required as the input to the charge pump 10, for the power supply voltage VDC=3V from an unused battery connected to the power supply line VDC.

(1) Activation of the Booster Circuit 200; until Vp1>Vref:

If the power supply voltage VDC is supplied from the battery to the power supply line VDC, it is divided by the voltage divider resistor 41 of the control section 40. At this time, a voltage Vp1 at the voltage dividing point P1 is input to the non-inverting input terminal of the comparator 42. The comparator 42 compares the voltage Vp1 with a reference voltage Vref from the reference voltage generator 43 input to its inverting input terminal (−). At the activation of the booster circuit 200, the power supply voltage VDC of the power supply line VDC rises from zero, and the voltage Vp1 at the voltage dividing point P1 also rises from zero. Until Vp1>Vref is satisfied, the voltage of the output terminal of the comparator 42 is “L”, and thus an “H” level of control signal is output through the inverter 45. This control signal is input to the control terminal 32a of the operational amplifier 32. The “H” level of control signal is also input to the gate of the MOS transistor 44 to turn on the MOS transistor 44. Since the MOS transistor 44 is now turned on, the voltage at the voltage dividing point P2 of the voltage divider resistor 41 equals to the ground voltage. As described above, the voltage at the voltage dividing point P1 is: Vp1=VDC*R2/(R1+R2). The resistance of each resistor R1, R2, and R3 of the voltage divider resistor 41 is set so as to keep the voltage of the output terminal of the comparator 42 to “L” level until the power supply voltage VDC reaches 2.7V, for example.

In the operational amplifier 32, on the other hand, the MOS transistor M8 is turned on by the “H” level control signal input to the control terminal 32a. The gate voltage of the MOS transistor M6 is thereby pulled down to the ground voltage to turn on and fully drive the MOS transistor M6.

At this time, the other circuits than the MOS transistors M6 and M8 which constitute the operational amplifier 32 are off. Hence, until Vp1>Vref, which is VDC>2.7V in this example, the initial power supply voltage VDC is supplied as Vci to the charge pump 10 through the MOS transistor M6 of the operational amplifier 32. The charge pump 10 thereby outputs Vo=2*Vci to the output terminal Vo.

Thus, when the power supply voltage VDC reaches 2.7V in the course of rising to 3V, the voltage Vo=2*Vci=5.4V is output. In the case of using a battery with a decreased power supply voltage VDC, which is, for example, the consumed battery with the power supply voltage VDC=2.7V, the voltage at the output terminal of the comparator 42 remains “L” even after the power supply voltage rises to 2.7V. The power supply voltage DC=2.7V is thus supplied as Vci to the charge pump 10 through the MOS transistor M6 of the operational amplifier 32. The charge pump 10 thereby outputs Vo=2*Vci=5.4V to the output terminal Vo.

(2) After Activation of the Booster Circuit 200; after Vp1>Vref

If the power supply voltage VDC further increases from 2.7V to satisfy Vp1>Vref, the voltage at the output terminal of the comparator 42 becomes “H” level, and thus an “L” level control signal is output through the inverter 45. This control signal is input to the control terminal 32a of the operational amplifier 32. The “L” level control signal is also input to the gate of the MOS transistor 44. The MOS transistor 44 is thereby turned off so that the R3 between the R2 of the voltage divider resistor 41 and the ground starts functioning as a resistor. As described above, the voltage of the first voltage dividing point P1 is: Vp1=VDC*(R2+R3)/(R1+R2+R3). The resistance of each resistor R1, R2, and R3 of the voltage divider resistor 41 is set so as to keep the voltage at the output terminal of the comparator 42 to “H” level until the power supply voltage satisfies VDC<2.6V, for example.

In the operational amplifier 32, on the other hand, an “L” level control signal input to the control terminal 32a turns off the MOS transistor M8 and turns on the other circuits than the MOS transistors M6 and M8 which constitute the operational amplifier 32. The D/A converter 21 thereby outputs an output voltage Vdac based on the input n-bit data. The output voltage Vdac is supplied as Vci to the charge pump 10 through the operational amplifier 32. The charge pump 10 outputs Vo=2*Vci to the output terminal Vo. While the power supply voltage VDC increases from 2.7V to 3.0V, the output voltage is Vdac<2.7V, and the voltage of Vci<2.7V is supplied to the charge pump 10; however, it causes no effect since the voltage of Vci<2.7V is already supplied thereto at the time of activation. When the power supply voltage VDC reaches 3.0V, the output voltage becomes Vdac=2.7V, and the charge pump 10 outputs Vo=2*Vci to the output terminal Vo.

Since the hysteresis effect is added to the detection of the power supply voltage VDC in the booster circuit 200, if the power supply voltage VDC decreases after activation, the output terminal of the comparator does not become “L” level until the power supply voltage reaches 2.6V in this example.

As described in the foregoing, the control section 40 detects a power supply voltage VDC and compares it with a reference value. Based on the comparison result, the control section 40 supplies the power supply voltage VDC to the charge pump through the MOS transistor M6 of the operational amplifier 32 until the power supply voltage VDC reaches a given voltage, such as 2.7V, for an unused power supply voltage VDC, such as 3V, for instance. Even if a power supply voltage VDC is as low as a given voltage of about 2.7V, for example, due to battery consumption, the power supply voltage VDC is supplied to the charge pump through the MOS transistor M6 of the operational amplifier 32. This allows outputting a desired boosted voltage until the power supply voltage VDC rises even when the power supply voltage VDC is relatively low.

Though the above embodiment describes the case of using a double boosting charge pump, another type of charge pump may be used. Further, not only a positive voltage charge pump, but also a negative voltage charge pump may be used.

It is apparent that the present invention is not limited to the above embodiment, that maybe modified and changed without departing from the scope and spirit of the invention.

1. A booster circuit comprising:
a charge pump;
a voltage supply section reducing a power supply voltage and supplying a voltage to the charge pump through an output metal-oxide-semiconductor (MOS) transistor of an operational amplifier; and
a drive MOS transistor maximizing a drive capacity of the output MOS transistor of the operational amplifier.

2. The booster circuit of claim 1, further comprising a control section turning on the drive MOS transistor if a power supply voltage is equal to or less than a given voltage.

3. The booster circuit of claim 2, wherein the control section stops an amplification function of the operational amplifier if the drive MOS transistor is turned on.

4. The booster circuit of claim 2, wherein the control section comprises:
a voltage divider resistor detecting a power supply voltage;
a comparator comparing a divided voltage of the voltage divider resistor with a reference voltage; and
a reference voltage generator generating a reference voltage.

5. The booster circuit of claim 2, wherein a hysteresis effect is added for setting a given voltage of the power supply voltage in the control section.

6. The booster circuit of claim 4, wherein a hysteresis effect is added for setting a given voltage of the power supply voltage in the control section.

7. The booster circuit of claim 1, wherein the voltage supply section comprises a digital/analog converter selecting a voltage used as the power supply voltage from a plurality of power supply voltages.
